(19) United States
(12) Patent Application Publication
(10) Pub. No.: US 2013/0071991 A1
(43) Pub. Date: Mar. 21, 2013

(54) Electrode Treatments for Enhanced DRAM Performance

(71) Applicants: Intermolecular, Inc., San Jose, CA (US); Elpida Memory, Inc., Tokyo (JP)

(72) Inventors: Xiangxin Rui, Campbell, CA (US); Takashi Arao, Higashihiroshima (JP); Hanhong Chen, Milpitas, CA (US); Naonori Fujiwara, Kure (JP); Edward Haywood, San Jose, CA (US); Toshiyuki Hirota, Higashihiroshima (JP); Takakazu Kiyomura, Higashihiroshima (JP); Kenichi Koyanagi, Higashihiroshima (JP); Sandra G. Malhotra, Fort Collins, CO (US)

(73) Assignees: ELPIDA MEMORY, INC, Tokyo (JP); INTERMOLECULAR, INC., San Jose, CA (US)

(21) Appl. No.: 13/677,239

(22) Filed: Nov. 14, 2012

Related U.S. Application Data
(63) Continuation of application No. 13/051,531, filed on Mar. 18, 2011.

(51) Int. Cl. H01L 21/02

(52) U.S. Cl. CPC H01L 21/02
USPC 438/396

(57) ABSTRACT

A method for fabricating a dynamic random access memory capacitor is disclosed. The method may comprise depositing a first titanium nitride (TiN) electrode; creating a first layer of titanium dioxide (TiO₂) on the first TiN electrode; depositing a dielectric material on the first layer of titanium dioxide; and depositing a second TiN electrode on the dielectric material.

### CROSS-REFERENCE TO RELATED APPLICATIONS

This application is a Continuation Application of U.S. patent application Ser. No. 13/051,531, filed on Mar. 18, 2011, which is herein incorporated by reference for all purposes.

This document relates to the subject matter of a joint research agreement between Intermolecular, Inc. and Elpida Memory, Inc.

### TECHNICAL FIELD

The present invention relates to the field of dynamic random access memory (DRAM) fabrication methods, and particularly to electrode treatments for enhanced DRAM performance.

### BACKGROUND

Dynamic Random Access Memory or DRAM uses capacitors to store bits of information within an integrated circuit. Some DRAM devices use Metal-Insulator-Metal or MIM capacitors. MIM capacitors in DRAM applications use insulating materials with a dielectric constant higher than that of SiO₂ (3.9). Such materials are referred to as high-K materials. Dielectric constant, or K value, is a measure of a material's ability to be polarized; polarization is closely associated with a material's ability to hold electrical charge. Therefore, the higher the dielectric constant of a material, the more electrical charge the material can hold. A capacitor's ability to hold electrical charge (capacitance) is a function of the surface area of the capacitor plates A, the distance between the capacitor plates d, and the dielectric constant or K value of the insulator ε.

$$C = \frac{A \cdot ɛ}{d} \qquad ( 1 )$$

The higher the K value, the smaller is the area of the capacitor needed for the same capacitance. Reducing the size of capacitors is important for reducing the size of integrated circuits.

As DRAM technologies scale down below 40 nm (referring to the average half-pitch of a memory cell, or half the distance between cells in a DRAM chip), manufacturers must reduce the equivalent oxide thickness of dielectric films in MIM capacitors to increase charge storage capacity. Equivalent oxide thickness (EOT) is inversely related to a dielectric's capability to store charge, and is expressed for different materials using a normalized measure of silicon dioxide (SiO2) as a reference

$$EOT = \frac{3.9}{ɛ} d \qquad ( 2 )$$

Where, d represents the physical thickness and ε represents the K value (i.e., dielectric constant) of a material. Thus, the smaller the EOT a dielectric material can achieve, the higher the capability of the dielectric to store charges in associated components, including capacitor, DRAM cell, and so forth.

Zirconium dioxide (ZrO₂), having a high dielectric constant of up to approximately 50, is one of the potential high-K dielectric materials for replacing SiO₂ in numerous applications. For instance, ZrO₂ may be utilized as the insulating dielectric material (i.e., the insulator) in a DRAM MIM capacitor.

Atomic layer deposition (ALD) is a thin film deposition method that may be utilized for depositing ZrO₂ films on a titanium nitride (TiN) electrode during DRAM MIM capacitor fabrication. ALD may be based on sequential pulsing of two gas phase reactants that are typically referred to as a precursor and an oxidizer. A precursor adsorbs on a substrate surface for a fixed period of time and is then purged. Subsequently, an oxidizer is pulsed onto the substrate for a fixed period of time and is also purged. This process is repeated to obtain a film thickness of interest. Precise thickness control is maintained because the precursor adsorbs in a self-limited fashion so that approximately one monolayer of precursor material reacts with each oxidizer pulse. ZrO₂ films deposited on the TiN electrode utilizing ALD method may require O₃ or H₂O as oxidizer in order to react with different Zr precursors (e.g., alkylamidos, alkylamido cyclopentadienyls, or other molecules) at a high temperature (200C to 400C).

To achieve stoichiometric ZrO₂ films, the O₃ or H₂O oxidizers may need to satisfy certain requirements (e.g. concentration or pulse time), as unsaturated reactions may result in incorrect composition, low dielectric constant and high leakage current (a phenomenon where current passes through an insulator, compromising storage capacity). Reactions between O₃ or H₂O and the TiN electrode, especially within an initial few nanometers of ZrO₂ deposition, may result in the formation of a TiNₓO_{y} interfacial layer which has an unpredictable, and likely low, dielectric constant. A TiNₓO_{y} interfacial layer (having a low dielectric constant) formed on the initial few nanometers of ZrO₂ deposition may reduce the overall dielectric constant of the insulator. Since the DRAM capacitor's ability to hold electrical charge is partially based on the dielectric constant (K value) of its insulator, having such a TiNₓO_{y} interfacial layer formed on the insulator may degrade the overall performance of the DRAM capacitor. Therefore, methods/processes are needed to prevent the formation of such TiNₓO_{y} interfacial layers in a DRAM capacitor fabrication process.

### BRIEF DESCRIPTION OF THE DRAWINGS

The numerous advantages of the present invention may be better understood by those skilled in the art by reference to the accompanying figures in which:

FIG. 1 is a flow diagram illustrating a DRAM capacitor fabrication process;

FIG. 2 is an illustration depicting a DRAM capacitor fabricated in accordance with the DRAM capacitor fabrication process as illustrated in FIG. 1;

FIG. 3 is an illustration depicting another DRAM capacitor fabricated in accordance with the DRAM capacitor fabrication process as illustrated in FIG. 1;

FIG. 4 is a flow diagram illustrating another DRAM capacitor fabrication process;

FIG. 5 is an illustration depicting a DRAM capacitor fabricated in accordance with the DRAM capacitor fabrication process as illustrated in FIG. 4; and

FIG. 6 is a flow diagram illustrating a method for treating a TiN electrode.

### DETAILED DESCRIPTION

Reference will now be made in detail to the presently preferred embodiments of the invention, examples of which are illustrated in the accompanying drawings.

The present disclosure is directed to a method for treating an electrode, such as a first electrode or a bottom electrode, prior to deposition of the dielectric material in a DRAM capacitor fabrication process. This treatment reduces or prevents the reactions between O₃ or H₂O ALD oxidizers and the TiN electrode during the dielectric deposition, and therefore reduces or prevents the formation of TiNₓO_{y} interfacial layer which may degrade the overall performance of the DRAM capacitor.

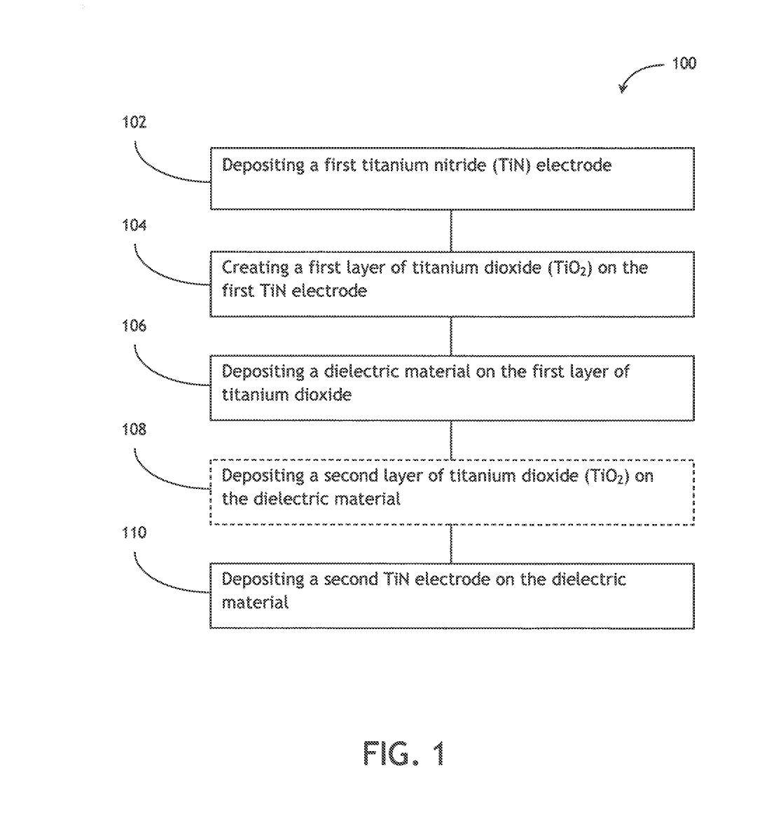

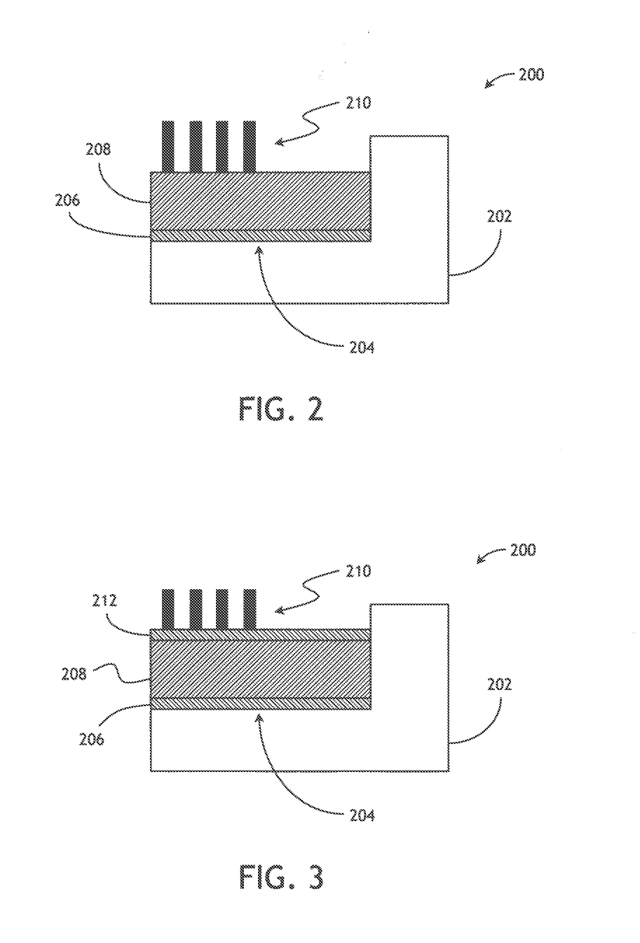

FIG. 1 shows a flow diagram illustrating steps performed by a DRAM capacitor fabrication process 100. The fabrication process 100 includes treating a TiN electrode prior to dielectric deposition. FIG. 2 schematically depicts a simple two-dimensional DRAM Metal-Insulator-Metal (MIM) capacitor 200 fabricated in accordance with the DRAM capacitor fabrication process 100. The DRAM capacitor 200 having dielectric deposition on the treated TiN electrode may satisfy the equivalent oxide thickness (EOT) and leakage specs for a 40 nm node and/or a high performance 30 nm node that utilizes ZrO₂ for dielectric materials.

Step 102 may deposit a first TiN electrode 202. The first TiN electrode 202 may also be referred to as the bottom electrode. The first TiN electrode defines a surface 204 for receiving the deposition of the dielectric materials. Treatment to the first TiN electrode 202 is provided to protect the surface 204 prior to the deposition of the dielectric materials.

Step 104 may create a first cover layer 206 to cover and protect the surface 204 prior to the deposition of the dielectric materials 208. Chemical vapor deposition or atomic layer deposition techniques may be utilized to deposit the cover layer on to the surface 204. In one embodiment, the first cover layer 206 may be a layer of titanium dioxide (TiO₂). TiO₂ is selected as a suitable cover layer material for its high-K value. The K value of TiO₂, in anatase phase, is approximately 40, and the K value of TiO₂ in rutile phase is approximately 90. Furthermore, TiO₂ may template tetragonal ZrO₂ formation which may have a higher K value compared to other phases of ZrO₂.

It is contemplated that atomic layer deposition or ALD techniques (as previously described) may be utilized to deposit the TiO₂ cover layer 206 on the surface 204. Alternatively, ozone (O₃) plasma may be utilized to soak the first TiN electrode 202 for a period of time to form the TiO₂ cover layer 206 on the surface 204. For example, a soak time of between approximately 10 minutes to 60 minutes, with concentration of O₃ between approximately 5 to 20 weight percent, may form a TiO₂ cover layer 206 having a thickness of between approximately 0.1 nm and approximately 1.5 nm. The soak time utilized in a preferred formation process may be approximately 30 minutes. It is noted that the K value of TiO₂ formed utilizing the formation techniques described above is expected to be higher than that of the TiNₓO_{y} interfacial layer, which may result after the deposition of the dielectric materials in step 106.

Step 106 may deposit the dielectric materials 208 on to the first cover layer 206. The dielectric materials may include ZrO₂ films, doped ZrO₂ films (e.g., aluminum-doped ZrO₂ and germanium-doped ZrO₂), or a combination of ZrO₂ films and doped ZrO₂ films. For example, atomic layer deposition techniques may be utilized to deposit the dielectric materials on to the first layer of TiO₂ 206. The first layer of TiO₂ 206 protects surface 204 of the first TiN electrode 202 and reduces or prevents reactions between O₃ or H₂O and the first TiN electrode 202 during the dielectric deposition. In this manner, the formation of TiNₓO_{y} interfacial layer may be reduced or prevented. Since the DRAM MIM capacitor's ability to hold electrical charge relies on the high dielectric constant (K value) of its insulator, reducing or preventing the formation of the TiNₓO_{y} interfacial layer (which has an unpredictable, and likely low, dielectric constant) on the insulator may improve the overall performance of the DRAM capacitor.

Additional DRAM capacitor fabrication steps may be carried out subsequently. For example, step 110 may deposit a second TiN electrode 210 on the dielectric materials 208 after the dielectric materials 208 have been deposited, forming the DRAM capacitor as illustrated in FIG. 2. The second TiN electrode 210 may also be referred to as the top electrode.

It is contemplated that a second cover layer 212 (shown in FIG. 3) may be utilized to cover and protect the dielectric materials 208. For example, upon deposition of the dielectric materials, step 108 may introduce a second cover layer 212 to cover the dielectric materials 208. In one embodiment, the second cover layer 212 may be a second layer of titanium dioxide (TiO₂). Step 110 may position the second TiN electrode 210 on top of the TiO₂ covered dielectric material, forming the DRAM capacitor as illustrated in FIG. 3.

Various cover layer thicknesses have been tested under different conditions (e.g., different Zr precursors and pedestal temperatures). Dielectric constant improvement is observed when the surface of the first TiN electrode is protected by the TiO₂ cover layer. Some improvements in current density (J) and equivalent oxide thickness (EOT) curve for a ZrO₂ dielectric layer are also observed when the surface of the first TiN electrode is protected by a TiO₂ cover layer less than 1.5 nm in thickness. In one embodiment, the first layer of TiO₂ may have a first thickness of between approximately 0.1 nm and approximately 1.5 nm, preferably between approximately 0.1 nm and approximately 1.0 nm. The second layer of TiO₂ may have a second thickness of between approximately 0.1 nm and approximately 1.5 nm, preferably between approximately 0.1 nm and approximately 1.0 nm. It is contemplated that the first thickness may or may not be substantially identical to the second thickness.

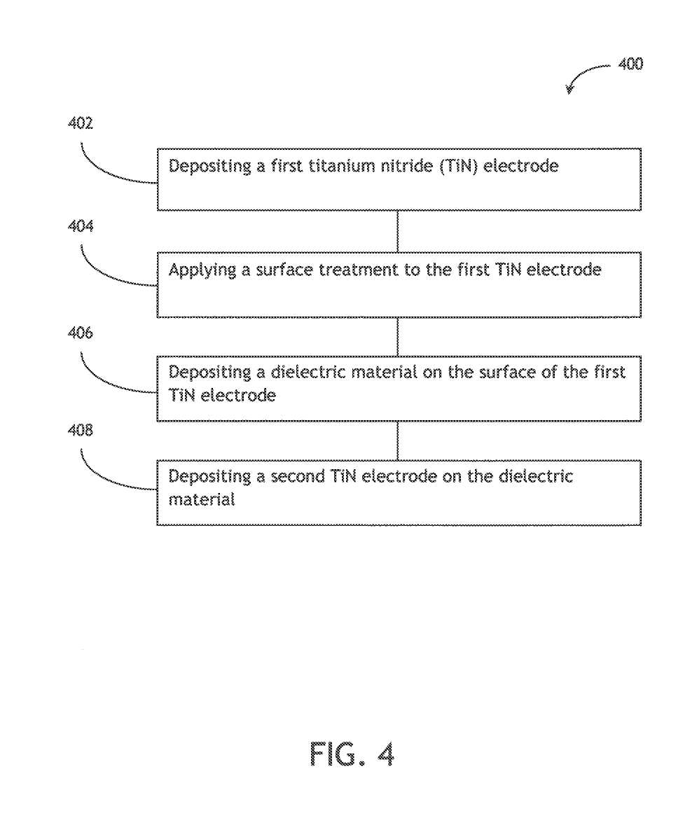

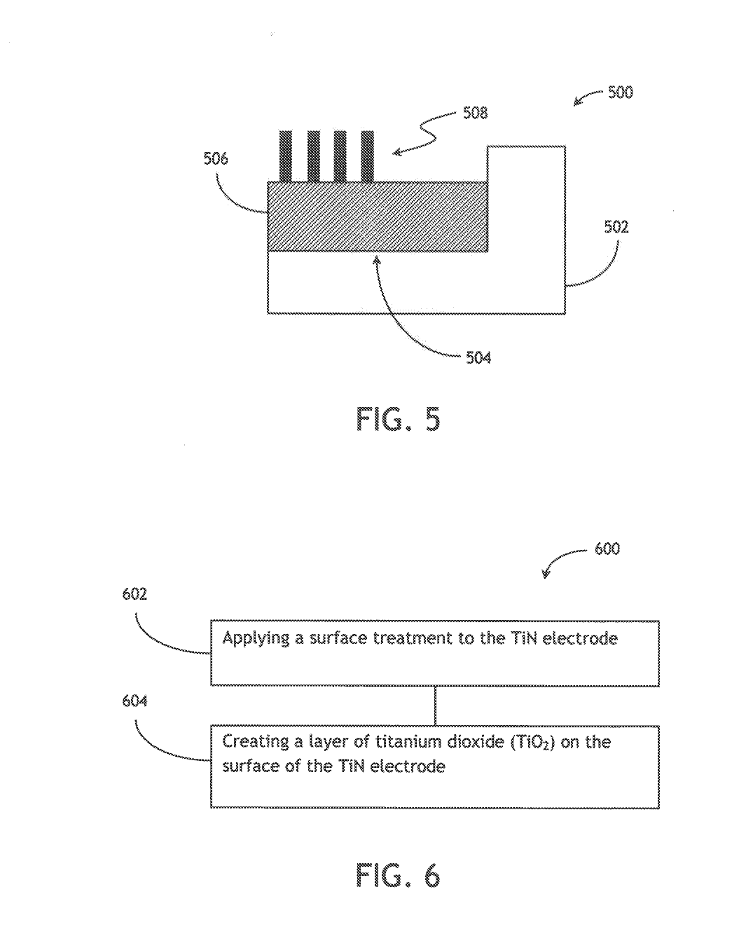

FIG. 4 shows a flow diagram illustrating steps performed by an alternative DRAM capacitor fabrication process 400. The fabrication process 400 also includes treating a first TiN electrode prior to dielectric deposition. FIG. 5 schematically depicts a simple two-dimensional DRAM MIM capacitor 500 fabricated in accordance with the DRAM capacitor fabrication process 400.

Step 402 may deposit a first TiN electrode 502. The first TiN electrode defines a surface 504 for receiving the deposition of the dielectric materials. Treatment to the first TiN electrode 502 is provided to protect the surface 504 prior to the deposition of the dielectric materials.

Step 404 may apply a surface treatment to the surface 504. For example, nitrogen (N₂), ammonia (NH₃) or nitrogen/hydrogen-mixture (N₂/H₂) plasma treatment of the first TiN electrode 502 may be utilized for hardening or surface modification purposes. In this manner, plasma discharge may be utilized to diffuse nitrogen into the surfaces of the first TiN electrode 502, hardening the surface 504. It is contemplated that other surface hardening techniques may also be utilized. For example, nitrogen (N₂), ammonia (NH₃) or nitrogen/hydrogen-mixture (N₂/H₂) thermal treatment (e.g., thermal annealing) of the first TiN electrode 502 may be utilized without departing from the spirit and scope of the present disclosure.

Step 406 may deposit the dielectric materials 506 on to the treated surface 504. The dielectric materials may include ZrO₂ films, doped ZrO₂ films (e.g., aluminum-doped ZrO₂ and germanium-doped ZrO₂), or a combination of ZrO₂ films and doped ZrO₂ films. For example, atomic layer deposition techniques may be utilized to deposit the dielectric materials on to the treated surface 504. Additional DRAM capacitor fabrication steps may be carried out subsequently. For example, step 408 may position the second TiN electrode 508 on the dielectric materials 506 after the dielectric materials 506 have been deposited, forming the DRAM capacitor as illustrated in FIG. 5.

Improvements in leakage reduction are observed when the surface of the first TiN electrode is hardened. The improvements may be significant when N₂/H₂ plasma treatment or NH₃ thermal treatment is utilized.

It is understood that while the TiN electrode being treated may be referred to as the bottom electrode contact (BEC) in a DRAM capacitor, the electrode treatment method of the present disclosure is not limited to the BEC. It is contemplated that the electrode treatment method may be utilized for treating electrode in any given orientation without departing from the spirit and scope of the present disclosure.

It is further contemplated that both the surface treatment and the deposition of one or more cover layers may be utilized for treating a TiN electrode. Referring to FIG. 6, a flow diagram illustrating steps performed by a TiN treatment method 600 is shown. The TiN treatment method 600 may be utilized for treating a TiN electrode for a DRAM capacitor. In one embodiment, step 602 may apply a treatment to one or more surfaces of the TiN electrode. For example, nitrogen (N₂), ammonia (NH₃) or N₂/H₂ plasma treatment of the TiN electrode may be utilized for hardening treatment purposes. In another example, nitrogen (N₂), ammonia (NH₃) or N₂/H₂ thermal treatment (e.g., thermal annealing) of the TiN electrode may be utilized. Step 604 may create a cover layer to cover and protect one or more surfaces of the TiN electrode. In one embodiment, the cover layer may be a layer of titanium dioxide (TiO₂). The TiO₂ cover layer may have a thickness of between approximately 0.1 nm and approximately 1.5 nm.

It is believed that the present invention and many of its attendant advantages will be understood by the foregoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof, it is the intention of the following claims to encompass and include such changes.

What is claimed is:

1. An method for forming a capacitor stack, the method comprising:
depositing a first electrode layer,
depositing a first cover layer adjacent to the first electrode layer,
depositing a dielectric layer adjacent to the first cover layer, and depositing a second electrode layer;
wherein each of the first and second electrode layers comprises TiN, and
wherein the first cover layer reduces or prevents reactions between O₃ or H₂O and the first electrode layer during depositing of the dielectric layer.

2. The method of claim 1, wherein the first cover layer has a thickness between 0.1 nm and 1.5 nm.

3. The method of claim 2, wherein the first cover layer has a thickness of less than 1.0 nm.

4. The method of claim 1, wherein the first cover layer comprises TiO₂.

5. The method of claim 4, wherein the TiO₂ is rutile phase.

6. The method of claim 1, wherein the first cover layer reduces or prevents the formation of TiNₓO_{y} during depositing of the dielectric layer.

7. The method of claim 1, further comprising a second cover layer disposed between the dielectric layer and the second electrode layer.

8. The method of claim 7, wherein the second cover layer has a thickness between 0.1 nm and 1.5 nm.

9. The method of claim 8, wherein the first cover layer has a thickness of less than 1.0 nm.

10. The method of claim 7, wherein the second cover layer comprises TiO₂.

11. The method of claim 1, wherein the dielectric layer comprises a high-K dielectric material.

12. The method of claim 11, wherein the dielectric layer comprises ZrO₂.

13. The method of claim 12, wherein the ZrO₂ has a tetragonal structure.

14. The method of claim 1, wherein the dielectric layer comprises at least one of ZrO₂ or doped ZrO₂.

15. The method of claim 1, wherein dielectric layer comprises at least one of aluminum-doped ZrO₂ or germanium-doped ZrO₂.

16. The method of claim 1, further comprising a hardened surface on the first electrode layer.

17. The method of claim 16, wherein the hardened surface is formed by surface plasma treatment in an atmosphere comprising at least one of: N₂, NH₃, or N₂/H₂.

18. The method of claim 16, wherein the hardened surface is formed by thermal treatment in an atmosphere comprising at least one of: N₂, NH₃, or N₂/H₂.
